(19) United States
(12) Patent Application Publication
(10) Pub. No.: US 2013/0329913 A1
(43) Pub. Date: Dec. 12, 2013

(54) VOLUME CONTROL ASSEMBLY AND ELECTRONIC DEVICE USING SAME

(71) Applicants: FIH (Hong Kong) Limited, Kowloon (HK); SHENZHEN FUTAIHONG PRECISION INDUSTRY CO., LTD., Shenzhen (CN)

(72) Inventors: XIAO-SHAN LI, Shenzhen (CN); CHIH-WEI CHANG, New Taipei (TW)

(21) Appl. No.: 13/911,349

(22) Filed: Jun. 6, 2013

(30) Foreign Application Priority Data
Jun. 12, 2012 (CN) 2012101919847

(51) Int. Cl. H03G 3/02

(52) U.S. Cl. CPC H03G 3/02
USPC 381/109

(57) ABSTRACT

A volume control assembly used for adjusting a volume of an electronic device includes a base, a vibration sensor secured on the base, and a control unit electronically connected to the vibration sensor. The base includes a sensing portion, the sensing portion includes a first end and a second end, and the first end and the second end are spaced from each other. The vibration sensor is located adjacent to one of the first end or the second end. The vibration sensor senses vibration of the sensing portion, and sends a vibration signal to the control unit. The control unit receives the vibration signal, and adjusts the volume of the electronic device according to the vibration signal.

### BACKGROUND

1. Technical Field

The disclosure generally relates to volume control assemblies, and particularly to a volume control assembly of an electronic device.

2. Description of the Related Art

A volume control assembly is often secured to a main body of an electronic device through clasp structures. However, there can be gaps between the volume control assembly and the main body, thus dust and vapor can easily get into the electronic device.

Therefore, there is room for improvement within the art.

### BRIEF DESCRIPTION OF THE DRAWINGS

Many aspects of an exemplary volume control assembly can be better understood with reference to the following drawings. The components in the drawings are not necessarily drawn to scale, the emphasis instead being placed upon clearly illustrating the principles of the exemplary volume control assembly. Moreover, in the drawings, like reference numerals designate corresponding parts throughout the several views. Wherever possible, the same reference numbers are used throughout the drawings to refer to the same or like elements of an embodiment.

FIG. 1 is an exploded view of an electronic device with a volume control assembly according to an exemplary embodiment.

FIG. 2 is an assembled view of the electronic device shown in FIG. 1.

FIG. 3 is a partially, cross-sectional view of the electronic device along line III-III of FIG. 2.

FIG. 4 is a block diagram of the volume control assembly shown in FIG. 1.

### DETAILED DESCRIPTION

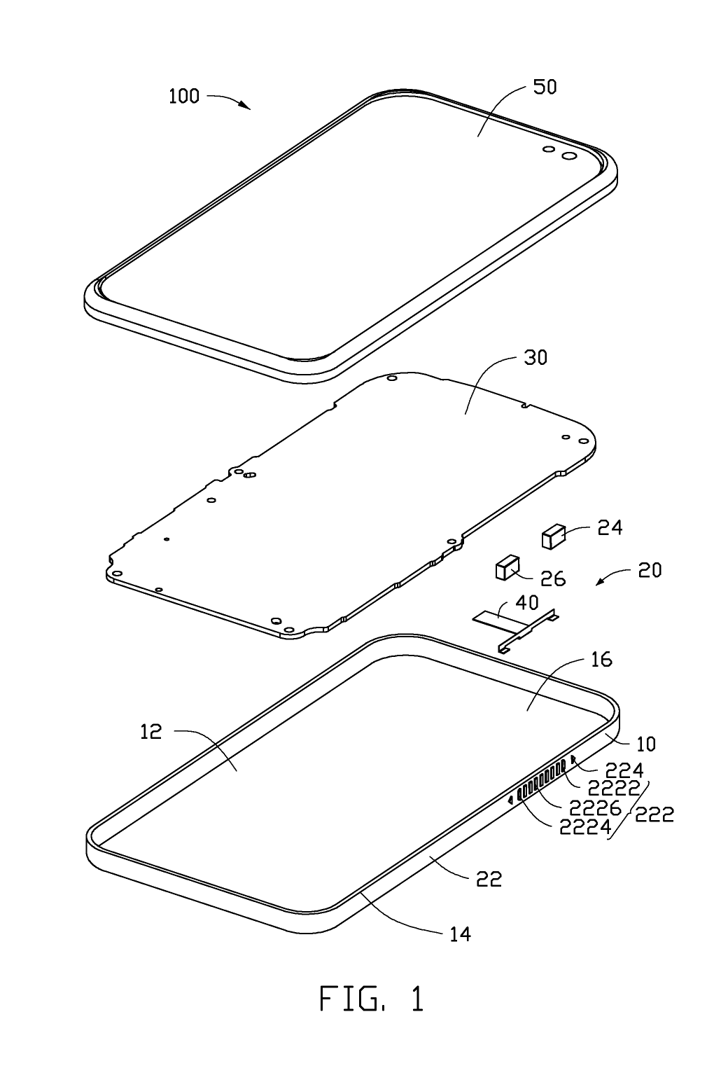

FIG. 1 shows a volume control assembly 20 secured on an electronic device 100, such as mobile phones and personal digital assistants, according to an exemplary embodiment.

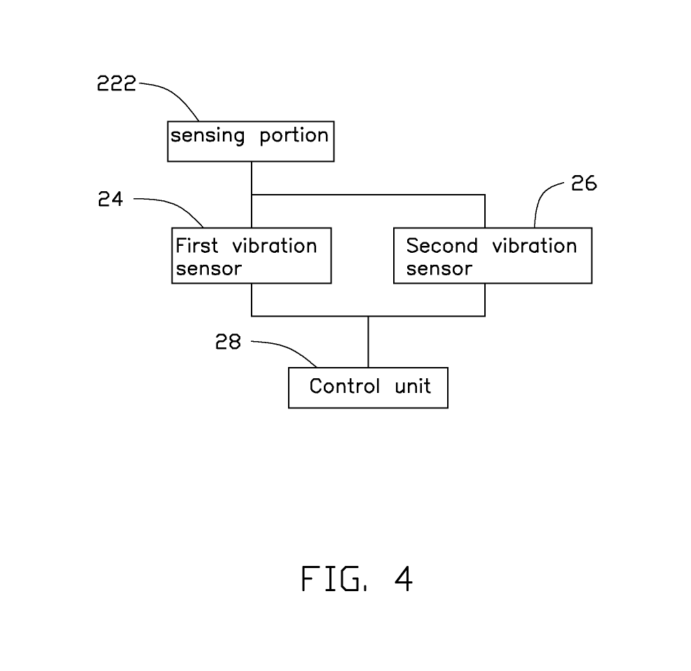

FIGS. 1 and 4 show that the electronic device 100 includes a main body 10, a volume control assembly 20, a circuit board 30, a flexible flat cable 40, and a cover 50 covering on the main body 10. The volume control assembly 20 is electronically connected to the circuit board 30 through the flexible flat cable 40. The volume control assembly 20 includes a base 22, a first vibration sensor 24, a second vibration sensor 26, and a control unit 28 (schematically shown in FIG. 4).

The main body 10 includes a bottom wall 12 and a peripheral wall 14. The peripheral wall 14 is perpendicularly connected to the bottom wall 12. The main body 10 defines a receiving groove 16 enclosed by the bottom wall 12 and the peripheral wall 14. The first vibration sensor 24, the second vibration sensor 26, the control unit 28, the circuit board 30, and the flexible flat cable 40 are received in the receiving groove 16.

The base 22 can be a portion of the peripheral wall 14, or an independent component attached to the peripheral wall 14. In the embodiment, the base 22 is integral with the peripheral wall 14. The base 22 includes a sensing portion 222 formed on a surface of the base 22 away from the receiving groove 16. The sensing portion 222 includes a first end 2222, a second end 2224, and a plurality of strip shaped protrusions 2226 located between the first end 2222 and the second end 2224. The plurality of protrusions 2226 are spaced from each other. When an object, such as a finger, slides on the plurality of protrusions 2226, the plurality of protrusions 2226 vibrate. The base 22 further includes two guide symbols 224, and the sensing portion 222 is located between the two guide symbols 224. In the embodiment, the two guide symbols 224 are triangular.

The first vibration sensor 24 and the second vibration sensor 26 are located on the base 22. The first vibration sensor 24 and the second vibration sensor 26 are used for sensing the degree and direction of vibration of the sensing portion 222, generating vibration signals and sending the vibration signals to the control unit 28.

The control unit 28 is located on the circuit 30, receives the vibration signals from the first vibration sensor 24 and/or the second vibration sensor 26 and adjusts the volume of the electronic device 100 according to the vibration signals.

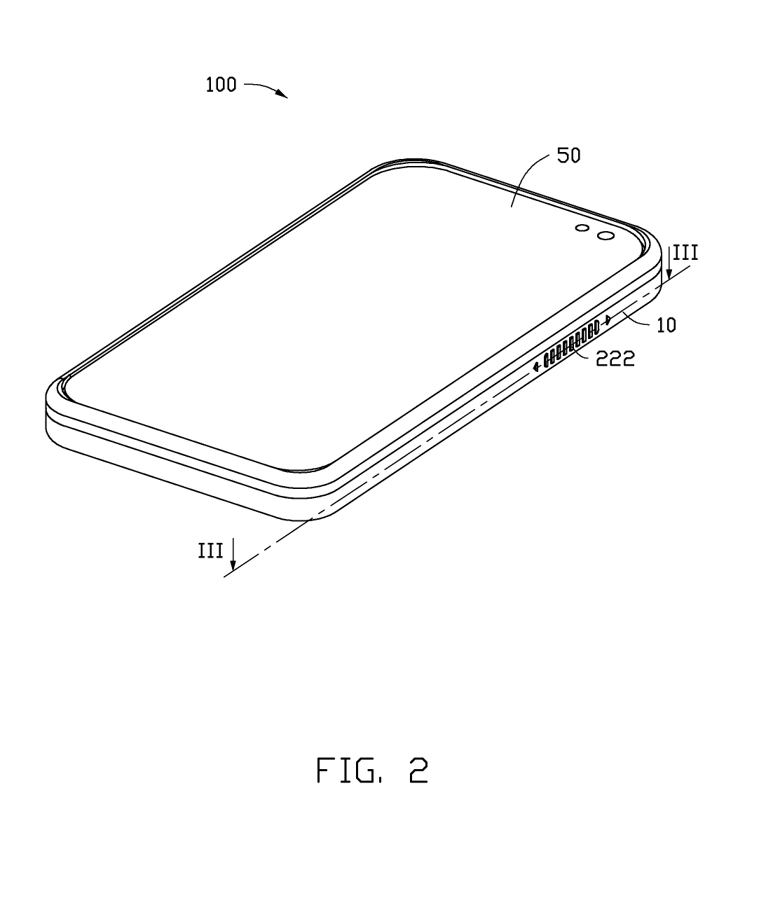

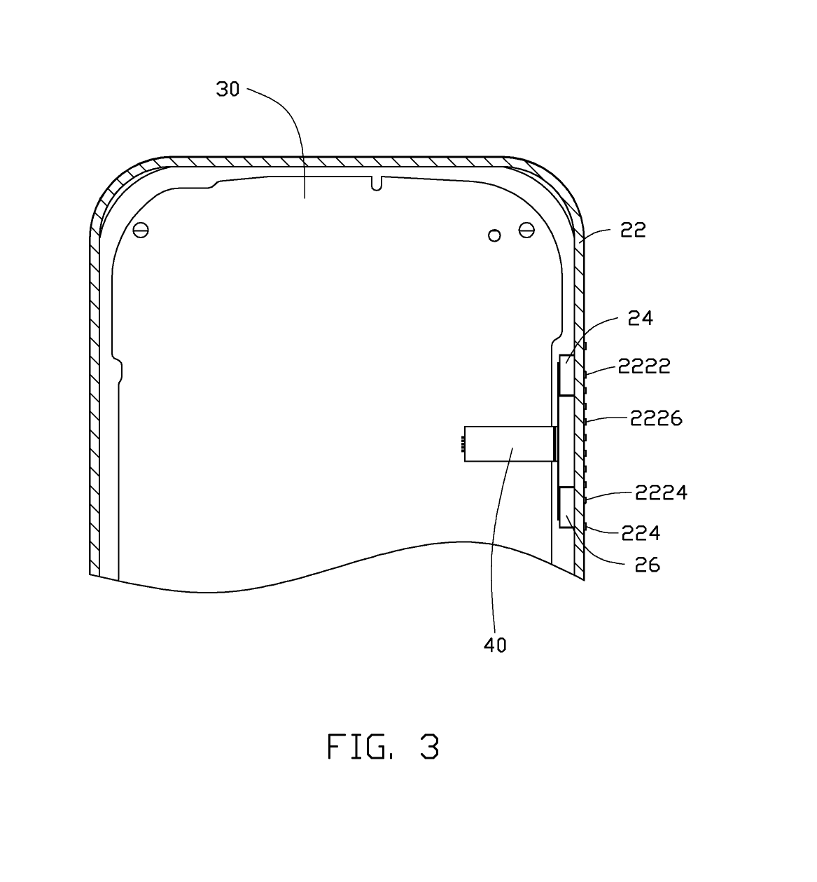

FIGS. 2 and 3 show that the assembly process of the electronic device 100 is as follows:

One end of the flexible flat cable 40 is electronically connected to the circuit board 30, and the other end of the flexible flat cable 40 is electronically connected to the first vibration sensor 24 and the second vibration sensor 26. The first vibration sensor 24 and the second vibration sensor 26 are received in the receiving groove 16 and are secured on the base 22. The first vibration sensor 24 is adjacent to the first end 2222, and the second vibration sensor 26 is adjacent to the second end 2224. The circuit board 30 is received in the receiving groove 16 and the cover 50 covers on the main body 10. Then the assembly process of the electronic device 100 is completed.

If a user needs to increase the volume of the electronic device 100, a finger of the user may slide from the second end 2224 to the first end 2222. The plurality of protrusions 2226 are made to vibrate successively and in a first direction by the finger. The closer the vibrating protrusion 2226 and the first vibration sensor 24 are to each other, the stronger the vibration sensed by the first vibration sensor 24. The first vibration sensor 24 adjacent to the first end 2222 senses the increasing degree of vibration of the plurality of protrusions 2226, and sends a first vibration signal to the control unit 28. The control unit 28 receives the first vibration signal and increases the volume of the electronic device 100 according to the first vibration signal. The above steps may be repeated to continue increasing the volume of the electronic device 100.

If the user needs to decrease the volume of the electronic device 100, the finger of the user may slide from the first end 2222 to the second end 2224. The plurality of protrusions 2226 are made to vibrate successively in a second direction, opposite to the first direction, by the finger. The closer the vibrating protrusion 2226 and the second vibration sensor 26 are to each other, the stronger the vibration sensed by the second vibration sensor 26. The second vibration sensor 26 adjacent to the second end 2224 senses the increasing degree of vibration of the plurality of protrusions 2226, and sends a second vibration signal to the control unit 28. The control unit 28 receives the second vibration signal and decreases the volume of the electronic device 100 according to the second vibration signal. The above steps may be repeated to continue decreasing the volume of the electronic device 100.

The first vibration sensor 24 and the second vibration sensor 26 sense the vibration (degree or direction) on the base 22, and the volume control assembly 20 is attached to the main body 10 without openings. Thus, the electronic device 100 has good waterproof and dustproof performance. Furthermore, fingers slide on the plurality of protrusions 2226 to adjust the volume of the electronic device 100, it is convenient to use.

In another embodiment, one of the first vibration sensor 24 or the second vibration sensor 26 can be omitted. For example, if there is only the first vibration sensor 24, when the finger slides from the second end 2224 to the first end 2222, the first vibration sensor 24 senses the increasing degree (also referring to a first degree) of vibration of the plurality of protrusions 2226, and sends a first vibration signal to the control unit 28 to increase the volume of the electronic device 100. When the finger slides from the first end 2222 to the second end 2224, the first vibration sensor 24 senses the decreasing degree (also referring to a second degree) of vibration of the plurality of protrusions 2226, and sends a second vibration signal to the control unit 28 to decrease the volume of the electronic device 100.

In another embodiment, the protrusions 2226 are replaced by a vibrator. The vibrator vibrates under an external force.

In another embodiment, the protrusions 2226 are replaced by grooves.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. A volume control assembly used for adjusting a volume of an electronic device, the volume control assembly comprising:
a base comprising a sensing portion, the sensing portion comprising a first end and a second end, the first end and the second end being spaced from each other;
a vibration sensor secured on the base and located adjacent to one of the first end and the second end; and
a control unit electronically connected to the vibration sensor;
wherein the vibration sensor senses vibration of the sensing portion, and sends a vibration signal to the control unit; the control unit receives the vibration signal, and adjusts the volume of the electronic device according to the vibration signal.

2. The volume control assembly as claimed in claim 1, wherein the sensing portion further comprises a plurality of protrusions located between the first end and the second end.

3. The volume control assembly as claimed in claim 2, wherein the plurality of protrusions are strip shaped and are spaced from each other; when an object slides on the plurality of protrusions, the plurality of protrusions vibrate.

4. The volume control assembly as claimed in claim 3, wherein when the vibration sensor senses a first degree of vibration of the plurality of protrusions, the vibration sensor sends a first vibration signal to the control unit to increase the volume; when the vibration sensor senses a second degree of vibration of the plurality of protrusions, the vibration sensor sends a second vibration signal to the control unit to decrease the volume.

5. The volume control assembly as claimed in claim 3, wherein when the plurality of protrusions are made to vibrate successively and in a first direction toward the vibration sensor, the vibration sensor sends a first vibration signal to the control unit to increase the volume; when the plurality of protrusions are made to vibrate successively in a second direction away from the vibration sensor, opposite to the first direction, the vibration sensor sends a second vibration signal to the control unit to decrease the volume.

6. The volume control assembly as claimed in claim 1, further comprising a second vibration sensor, wherein the vibration sensor is located adjacent to the first end, and the second vibration sensor is located adjacent to the second end, the vibration sensor senses an increasing degree vibration of the sensing portion and sends a first vibration signal to the control unit to increase the volume, the second vibration sensor senses an increasing degree of vibration of the sensing portion and sends a second vibration signal to the control unit to decrease the volume.

7. The volume control assembly as claimed in claim 6, wherein the vibration sensor and the second vibration sensor are electronically connected to the control unit through flexible flat cables.

8. The volume control assembly as claimed in claim 1, wherein the base is integral with the electronic device.

9. The volume control assembly as claimed in claim 1, wherein the sensing portion is located on a side of the base, and the vibration sensor opposite to the sensing portion is located on the other side of base.

10. An electronic device, comprising:
a main body comprising a sensing portion, the sensing portion comprising a first end and a second end, the first end and the second end being spaced from each other;
a vibration sensor secured on the main body and located adjacent to one of the first end and the second end; and
a control unit electronically connected to the vibration sensor;
wherein the vibration sensor senses vibration of the sensing portion, and sends a vibration signal to the control unit; the control unit receives the vibration signal, and adjusts the volume of the electronic device according to the vibration signal.

11. The electronic device as claimed in claim 10, wherein the sensing portion further comprises a plurality of protrusions located between the first end and the second end.

12. The electronic device as claimed in claim 11, wherein the plurality of protrusions are strip shaped and are spaced from each other; when an object slides on the plurality of protrusions, the plurality of protrusions vibrate.

13. The electronic device as claimed in claim 12, wherein when the vibration sensor senses a first degree of vibration of the plurality of protrusions, the vibration sensor sends a first vibration signal to the control unit to increase the volume; when the vibration sensor senses a second degree of vibration of the plurality of protrusions, the vibration sensor sends a second vibration signal to the control unit to decrease the volume.

14. The electronic device as claimed in claim 13, wherein when the plurality of protrusions are made to vibrate successively and in a first direction toward the vibration sensor, the vibration sensor sends a first vibration signal to the control unit to increase the volume; when the plurality of protrusions are made to vibrate successively in a second direction away from the vibration sensor, opposite to the first direction, the vibration sensor sends a second vibration signal to the control unit to decrease the volume.

15. The electronic device as claimed in claim 10, further comprising a second vibration sensor, wherein the vibration sensor is located adjacent to the first end, and the second vibration sensor is located adjacent to the second end, the vibration sensor senses an increasing degree vibration of the sensing portion and sends a first vibration signal to the control unit to increase the volume, the second vibration sensor senses an increasing degree of vibration of the sensing portion and sends a second vibration signal to the control unit to decrease the volume.

16. The electronic device as claimed in claim 10, wherein the vibration sensor is electronically connected to the control unit through a flexible flat cable.
